(19) United States
(12) Patent Application Publication
(10) Pub. No.: US 2012/0062274 A1
(43) Pub. Date: Mar. 15, 2012

(54) SCHMITT CIRCUIT

(75) Inventor: Nobu Yamaguchi, Tokyo (JP)

(73) Assignee: KABUSHIKI KAISHA TOSHIBA, Tokyo (JP)

(21) Appl. No.: 13/069,574

(22) Filed: Mar. 23, 2011

(30) Foreign Application Priority Data
Sep. 10, 2010 (JP) 2010-202971

(51) Int. Cl. H03K 19/0948; H03K 19/017; H03K 19/003

(52) U.S. Cl. 326/24; 326/22; 326/23

(57) ABSTRACT

The Schmitt circuit includes a first logic circuit that receives an output signal of the input logic circuit and has a first threshold voltage. The Schmitt circuit includes a second logic circuit that receives the output signal of the input logic circuit and has a second threshold voltage lower than the first threshold voltage. The Schmitt circuit includes a variable resistance circuit that adjusts the threshold voltage of the input logic circuit in accordance with an output signal of the first logic circuit and an output signal of the second logic circuit. The Schmitt circuit includes a third logic circuit that receives the output signal of the first logic circuit and the output signal of the second logic circuit, outputs a floating potential in the case where a potential of an input signal of the third logic circuit is between the first threshold voltage and the second threshold voltage, and outputs a fixed potential in the case where the potential of the input signal of the third logic circuit is equal to or exceeds the first threshold voltage or is equal to or below the second threshold voltage.

### CROSS-REFERENCE TO RELATED APPLICATION

This application is based upon and claims the benefit of priority from the prior Japanese Patent Application No. 2010-202971, filed on Sep. 10, 2010, the entire contents of which are incorporated herein by reference.

### FIELD

Embodiments described herein relate generally to a Schmitt circuit.

### BACKGROUND

In the conventional art, in regard to a semiconductor integrated circuit using a CMOS technology that can easily reduce power consumption, a Schmitt circuit having a hysteretic characteristic is used in the input circuit and the like to prevent chattering or mixture of noise.

### BRIEF DESCRIPTION OF THE DRAWINGS

FIG. 1 is a circuit diagram showing an example of the configuration of a Schmitt circuit 100 according to a first embodiment;

FIG. 2 is a figure showing the relationship between the logical levels of the output signals X2 and X3 of the first and second logic circuits C1 and C2 and the logical level of the output signal X4 of the third logic circuit C3;

FIG. 3 is a waveform diagram showing the waveform of each signal in the Schmitt circuit 100 shown in FIG. 1;

FIG. 4 is a circuit diagram showing an example of the configuration of a Schmitt circuit 200 according to the second embodiment;

FIG. 5 is a figure showing an example of the logical level of the output of the NOR circuit C31 shown in FIG. 4;

FIG. 6 is a figure showing an example of the logical level of the output of the XOR circuit C32 shown in FIG. 4; and

FIG. 7 shows an example of the logical level of the output of the multiplexer C33 shown in FIG. 4.

### DETAILED DESCRIPTION

A Schmitt circuit according to an embodiment, includes an input terminal into which an input signal is input. The Schmitt circuit includes an output terminal from which an output signal is output. The Schmitt circuit includes an input logic circuit that receives the input signal and has a threshold voltage that is variable. The Schmitt circuit includes a first logic circuit that receives an output signal of the input logic circuit and has a first threshold voltage. The Schmitt circuit includes a second logic circuit that receives the output signal of the input logic circuit and has a second threshold voltage lower than the first threshold voltage. The Schmitt circuit includes a variable resistance circuit that adjusts the threshold voltage of the input logic circuit in accordance with an output signal of the first logic circuit and an output signal of the second logic circuit. The Schmitt circuit includes a third logic circuit that receives the output signal of the first logic circuit and the output signal of the second logic circuit, outputs a floating potential in the case where a potential of an input signal an input signal of the third logic circuit is between the first threshold voltage and the second threshold voltage, and outputs a fixed potential in the case where the potential of the input signal of the third logic circuit is equal to or exceeds the first threshold voltage or is equal to or below the second threshold voltage. The Schmitt circuit includes a signal holding circuit that connected to the output terminal and holds an output of the third logic circuit.

Hereafter, embodiments of the present invention will be described with reference to the drawings.

### First Embodiment

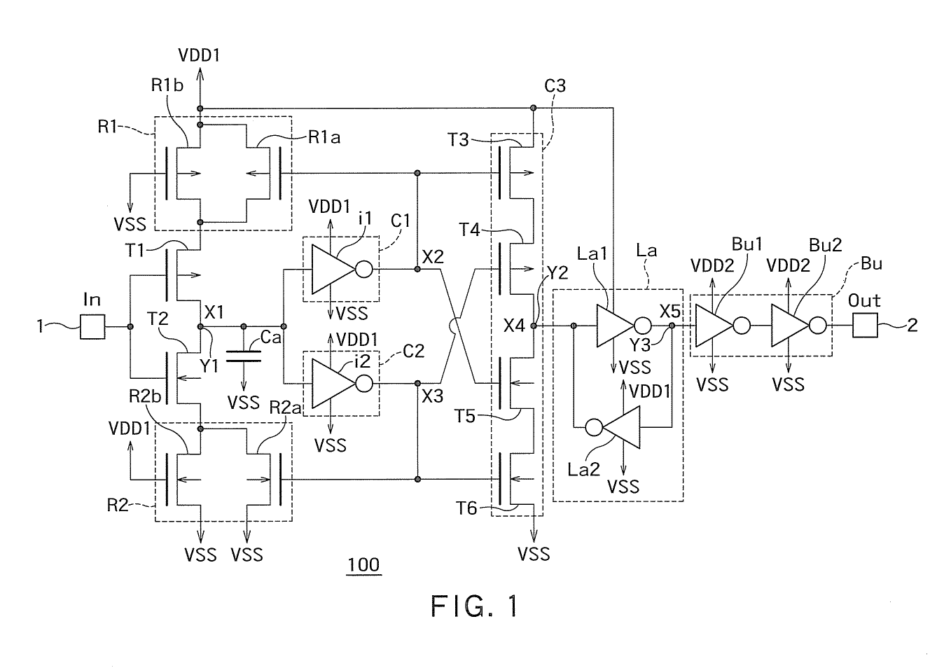

FIG. 1 is a circuit diagram showing an example of the configuration of a Schmitt circuit 100 according to a first embodiment.

As shown in FIG. 1, the Schmitt circuit 100 includes an input terminal 1, an output terminal 2, a first conductivity type first transistor (pMOS transistor) T1, a second conductivity type second transistor (nMOS transistor) T2, a first logic circuit C1, a second logic circuit C2, a third logic circuit C3, a first variable resistance circuit R1, a second variable resistance circuit R2, a latch circuit (signal holding circuit) La, an output buffer Bu, and a capacitor Ca.

An input signal In is input to the input terminal 1.

The output terminal 2 outputs an output signal Out.

One end (source) of the first transistor T1 is connected to a first potential (power supply potential) VDD1 through the variable resistance circuit R1 and a gate of the first transistor T1 is connected to the input terminal 1.

One end (drain) of the second transistor T2 is connected to the other end (drain) of the first transistor T1. The other end (source) of the second transistor T2 is connected to a second potential (ground potential) VSS different from the first potential VDD1 through the variable resistance circuit R2. A gate of the second transistor T2 is connected to the input terminal 1.

The first and second transistors T1 and T2 constitute an input logic circuit (inverter). The input logic circuit receives the input signal In and the threshold voltage of the input logic circuit is variable.

The first logic circuit C1 receives a signal X1 that is output from the output terminal Y1 disposed between the other end (drain) of the first transistor T1 and one end (drain) of the second transistor T2. The first logic circuit C1 has a first threshold voltage Vth1. The first logic circuit C1 compares a voltage of the signal X1 with the first threshold voltage Vth1 and inverts the logical level of an output signal X2, on the basis of the comparison result (for example, in the case where the voltage of the signal X1 changes thereby to exceed the first threshold voltage Vth1).

The first logic circuit C1 is a first inverter X1 that outputs the signal X2 obtained by inverting the logical level of the signal X1 output from the output unit Y1, on the basis of the first threshold voltage Vth1.

The second logic circuit C2 has a second threshold voltage Vth2 that is different form the first threshold voltage Vth1. The second logic circuit C2 compares the voltage of the signal X1 output from the output unit Y1 with the second threshold voltage Vth2 and inverts the logical level of an output signal X3, on the basis of the comparison result (for example, in the case where the voltage of the signal X1 changes thereby to exceed the second threshold voltage Vth2). In this case, the first threshold voltage Vth1 is set to be higher than the second threshold voltage Vth2.

The second logic circuit C2 is a second inverter i2 that outputs the signal X3 obtained by inverting the logical level of the signal X1 output from the output unit Y1, on the basis of the second threshold voltage Vth2.

The first variable resistance circuit R1 is connected between the first potential VDD1 and one end (source) of the first transistor T1 and the resistance value of the first variable resistance circuit R1 is controlled according to the output X2 from the first logic circuit C1.

The first variable resistance circuit R1 includes, for example, a first conductivity type first resistance transistor (pMOS transistor) R1a and a first conductivity type second resistance transistor (pMOS transistor) R1b.

A first resistance transistor (pMOS transistor) R1a is connected between the first potential VDD1 and one end (source) of the first transistor T1 and the gate of the first resistance transistor R1a is connected to the output X2 of the first logic circuit C1.

The second resistance transistor (pMOS transistor) R1b is connected in parallel to the first resistance transistor R1a between the first potential VDD1 and one end (source) of the first transistor T1. A fixed voltage (for example, ground voltage) is applied to the gate of the second resistance transistor R1b, so that a current flows.

The second variable resistance circuit R2 is connected between the second potential VSS and the other end (source) of the second transistor T2 and the resistance value thereof is controlled according to the output from the second logic circuit C2.

The second variable resistance circuit R2 includes a second conductivity type third resistance transistor (nMOS transistor) R2a and a second conductivity type fourth resistance transistor (nMOS transistor) R2b.

The third resistance transistor (nMOS transistor) R2a is connected between the second potential VSS and the other end (drain) of the second transistor T2 and the gate thereof is connected to the output X3 of the second logic circuit C2.

A fourth resistance transistor (nMOS transistor) R2b is connected in parallel to the third resistance transistor R2a between the second potential VSS and the other end (source) of the second transistor T2. A fixed voltage (for example, power supply potential) is applied to the gate of the fourth resistance transistor R2b, so that a current flows.

In the case where the logical level of the signal X2 is a “High” level and the logical level of the signal X3 is a “Low” level, the first resistance transistor R1a is turned off and the third resistance transistor R2a is turned off. At this time, a threshold voltage of the Schmitt circuit 100 is defined as a first reference voltage.

In the case where the logical level of the signal X2 is a “Low” level and the logical level of the signal X3 is a “High” level, the first resistance transistor R1a is turned on and the third resistance transistor R2a is turned on. At this time, the threshold voltage of the Schmitt circuit 100 itself is defined as a second reference voltage.

In the case where the sizes of the resistance transistors are equal to each other, the first reference voltage and the second reference voltage become equal to each other.

In the case where the logical level of each of the signals X2 and X3 is a “High” level, the first resistance transistor R1a is turned off and the third resistance transistor R2a is turned on, so that the resistance value of the second variable resistance circuit R2 decreases. Thereby, the threshold voltage of the Schmitt circuit 100 itself becomes lower than the first and second reference voltages.

Meanwhile, in the case where the logical level of each of the signals X2 and X3 is a “Low” level, the first resistance transistor R1a is turned on and the third resistance transistor R2a is turned off, so that the resistance value of the first variable resistance circuit R1 decreases. Thereby, the threshold voltage of the Schmitt circuit 100 itself becomes higher than the first and second reference voltages.

As such, the first and second variable resistance circuits R1 and R2 adjust the threshold voltage of the input logic circuit according to the output signal of the first logic circuit and the output signal of the second logic circuit. The Schmitt circuit 100 is configured such that the threshold voltage thereof varies.

The capacitor Ca is connected between the output unit Y1 and the fixed potential (for example, second potential VSS). The capacitor Ca adjusts the signal speed of the inverter that is constituted by the first and second transistors T1 and T2.

The capacitor Ca is provided according to a required design condition. However, the capacitor Ca may be omitted as necessary.

The third logic circuit C3 outputs any one of a third potential (in this case, the first potential VDD1 is selected), a fourth potential (in this case, the second potential VSS is selected) different from the third potential, and the floating potential VF, which is floating from the third and fourth potentials, as a signal X4 from the output unit Y2, according to the output signal X2 from the first logic circuit C1 and the output signal X3 from the second logic circuit C2. Specifically, in the case where the potential of the input signal In is between the first threshold voltage Vth1 and the second threshold voltage Vth2, the third logic circuit C3 outputs the floating potential which is floating. In the case where the potential of the input signal In is equal to or exceeds the first threshold voltage Vth1 or is equal to or below the second threshold voltage Vth2, the third logic circuit C3 outputs the fixed potential (third or fourth potential).

The third logic circuit C3 includes a first conductivity type third transistor (pMOS transistor) T3, a first conductivity type fourth transistor (pMOS transistor) T4, a second conductivity type fifth transistor (nMOS transistor) T5, and a second conductivity type sixth transistor (nMOS transistor) T6.

The third transistor T3 is connected to the fourth transistor T4 in series between the third potential VDD1 and the output unit Y2 (connection portion between the fourth transistor T4 and the fifth transistor T5) of the third logic circuit C3, and the gate thereof is connected to the output X2 of the first logic circuit C1.

The gate of the fourth transistor T4 is connected to the output X3 of the second logic circuit C2.

The fifth transistor T5 is connected to the sixth transistor T6 in series between the fourth potential VSS and the output unit Y2 of the third logic circuit C3, and the gate thereof is connected to the output X2 of the first logic circuit C1.

The gate of the sixth transistor T6 is connected to the output X3 of the second logic circuit C2.

The latch circuit La latches the signal X4 that is output from the third logic circuit C3 and outputs a signal X5.

The latch circuit La includes a first latching inverter La1 and a second latching inverter La2.

The input of the first latching inverter La1 is connected to the output unit Y2 of the third logic circuit C3 and the output thereof is connected to the input of an output buffer Bu.

The input of the second latching inverter La2 is connected to the output of the first latching inverter La1 and the output thereof is connected to the output unit Y2 of the third logic circuit C3.

The input of the output buffer Bu is connected to the output unit Y3 of the latch circuit La and the output thereof is connected to the output terminal 2. The output buffer Bu outputs a signal obtained by amplifying the input signal X5 as an output signal Out, to the output terminal 2.

For example, the output buffer Bu includes, for example, an even number of output inverters Bu1 and Bu2 that are connected in series between the output unit Y3 of the latch circuit La and the output terminal 2. The fifth potential (for example, potential lower than the power supply potential described above is selected) VDD2 is supplied to the output inverters Bu1 and Bu2.

Next, an example of the operation of the Schmitt circuit 100 that has the above configuration will be described.

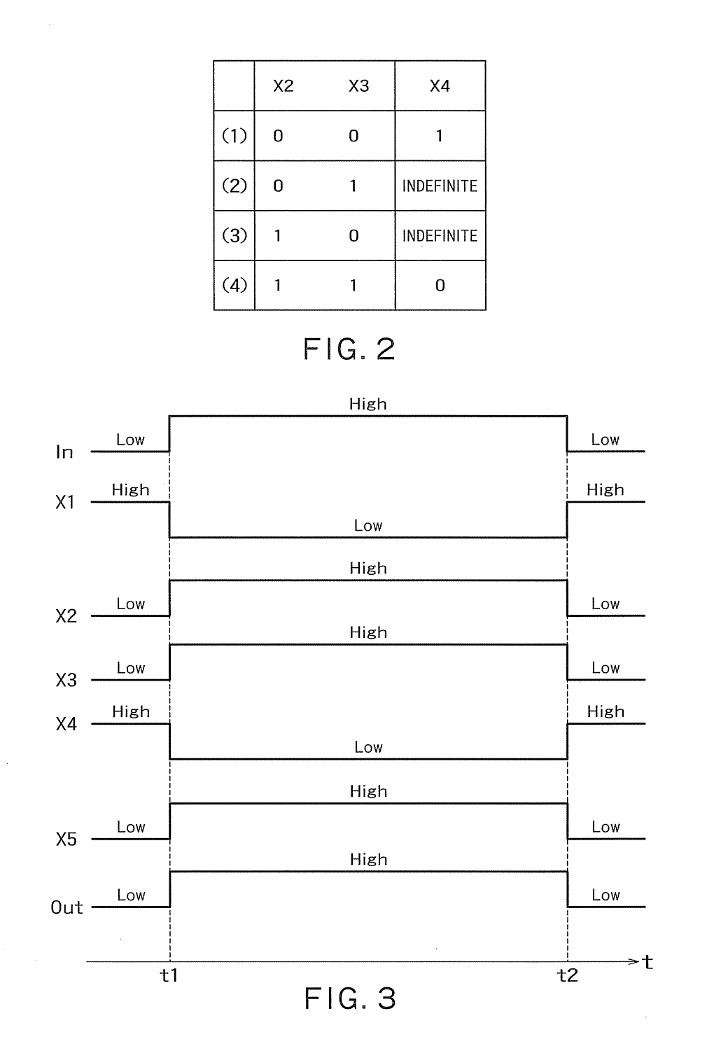

FIG. 2 shows the relationship between the logical levels of the output signals X2 and X3 of the first and second logic circuits C1 and C2 and the logical level of the output signal X4 of the third logic circuit C3.

As shown in FIG. 2, when the logical level of the output signal X2 of the first logic circuit C1 is “0” (“Low” level) and the logical level of the output signal X3 of the second logic circuit C2 is “0” (“Low” level), the logical level of the output signal X4 of the third logic circuit C3 becomes “1” (“High” level) (state (1)).

For example, in the state (1), the third and fourth transistors T3 and T4 are turned on and the fifth and sixth transistors T5 and T6 are turned off. Therefore, the output signal X4 of the output unit Y2 of the third logic circuit C3 becomes the third potential VDD1 (“High” level).

In the state (1), the latch circuit La outputs the signal X5 that has the logical level of “0” (“Low” level) according to the signal X4 where the logical level is “1” (“High” level).

When the logic of the output signal X2 of the first logic circuit C1 is “0” (“Low” level) and the logical level of the output signal X3 of the third logic circuit C2 is “1” (“High” level), the logical level of the output signal X4 of the third logic circuit C3 becomes indefinite (state (2)).

For example, in the state (2), since the third and sixth transistors T3 and T6 are turned on and the fourth and fifth transistors T4 and T5 are turned off, the output signal X4 of the output unit Y2 of the third logic circuit C3 becomes the floating potential that is floating from the third and fourth potentials VDD1 and VSS.

In the state (2), the latch circuit La outputs the signal X5 where the previously output logical level is maintained, according to the signal X4 where the logical level is indefinite. Therefore, the output signal of the Schmitt circuit does not become indefinite and noise is not generated in the output.

When the logical level of the output signal X2 of the first logic circuit C1 is “1” (“High” level) and the logical level of the output signal X3 of the second logic circuit C2 is “0” (“Low” level), the logical level of the output signal X4 of the third logic circuit C3 becomes indefinite (state (3)).

For example, in the state (3), since the fourth and fifth transistors T4 and T5 are turned on and the third and sixth transistors T3 and T6 are turned off, the output signal X4 of the output unit Y2 of the third logic circuit C3 becomes the floating potential VF that is floating from the third and fourth potentials VDD1 and VSS.

In the state (3), the latch circuit La outputs the signal X5 where the previously output logical level is maintained, according to the signal X4 where the logic is indefinite. Therefore, the output signal of the Schmitt circuit does not become indefinite and noise is not generated in the output.

When the logical level of the output signal X2 of the first logic circuit C1 is “1” (“High” level) and the logical level of the output signal X3 of the second logic circuit C2 is “1” (“High” level), the logical level of the output signal X4 of the third logic circuit C3 becomes “0” (“Low” level) (state (4)).

For example, in the state (4), since the fifth and sixth transistors T5 and T6 are turned on and the third and fourth transistors T3 and T4 are turned off, the output signal X4 of the output unit Y2 of the third logic circuit C3 becomes the fourth potential VSS (“Low” level).

In the state (4), the latch circuit La outputs the signal X5 having the logical level of “1” (“High” level), according to the signal X4 where the logical level is “0” (“Low” level).

FIG. 3 is a waveform diagram showing the waveform of each signal in the Schmitt circuit 100 shown in FIG. 1.

As shown in FIG. 3, at time t1, if the logical level of the input signal In changes from a “Low” level to a “High” level, the first transistor T1 is turned off and the second transistor T2 is turned on. Therefore, the logical level of the signal X1 changes from a “High” level to a “Low” level.

Thereby, the logical level of the output signal X2 of the first logic circuit C1 changes from a “Low” level to a “High” level and the logical level of the output signal X3 of the second logic circuit C2 changes from a “Low” level to a “High” level.

As described above, since the fifth and sixth transistors T5 and T6 are turned on and the third and fourth transistors T3 and T4 are turned off. Therefore, the output signal X4 of the output unit Y2 of the third logic circuit C3 becomes the fourth potential VSS (“Low” level).

As described above, the latch circuit La outputs the signal X5 having a “High” level, according to the signal X4 having a “Low” level.

The buffer circuit Bu outputs the output signal Out that has the same logical level as the logic of the signal X5.

As described above, the threshold voltage Vth1 of the first logic circuit C1 is higher than the threshold voltage Vth2 of the second logic circuit C2. Therefore, although not shown in FIG. 3, during a minute period around the time t1, when the logical level of the signal X1 changes from a “High” level to a “Low” level, timing at which the logical level of the signal X2 changes to a “High” level is earlier than timing at which the logical level of the signal X3 changes to a “High” level. That is, the state changes in the order from the state (1) shown in FIG. 2, to the state (3), and finally to the state (4).

Therefore, during the minute period, the state (3) shown in FIG. 2 is present. In the state (3), the latch circuit La maintains the logical level of the output signal X5 at a “Low” level.

Next, at time t2, if the logical level of the input signal In changes from a “High” level to a “Low” level, the first transistor T1 is turned on and the second transistor T2 is turned off. Therefore, the logical level of the signal X1 changes from a “Low” level to a “High” level.

Thereby, the logical level of the output signal X2 of the first logic circuit C1 changes from a “High” level to a “Low” level and the logical level of the output signal X3 of the second logic circuit C2 changes from a “High” level to a “Low” level.

As described above, since the fifth and sixth transistors T5 and T6 are turned off and the third and fourth transistors T3 and T4 are turned on. Therefore, the output signal X4 of the output unit Y2 of the third logic circuit C3 becomes the third potential VDD1 (“High” level).

As described above, the latch circuit La outputs the signal X5 having a “Low” level, according to the signal X4 having a “High” level. The buffer circuit Bu outputs the output signal Out that has the same logical level as the logical level of the signal X5.

As described above, the threshold voltage Vth1 of the first logic circuit C1 is higher than the threshold voltage Vth2 of the second logic circuit C2. Therefore, although not shown in FIG. 3, during a minute period around time t2, when the logical level of the signal X1 changes from a “Low” level to a “High” level, timing at which the logical level of the signal X2 changes to a “Low” level comes later than timing at which the logical level of the signal X3 changes to a “Low” level. That is, the state changes from the state (4) shown in FIG. 2, to the state (3), and finally to the state (1).

Therefore, during the minute period, the state (3) shown in FIG. 2 is present. In the state (3), the latch circuit La maintains the logical level of the output signal X5 at a “High” level.

As such, the Schmitt circuit 100 does not have a DC path where noise is output, and outputs the output signal Out where the logical level is definite, according to the input signal In.

That is, according to the Schmitt circuit according to the first embodiment, the transmission of the noise can be suppressed.

### Second Embodiment

In the first embodiment, the example of the Schmitt circuit that can suppress the transmission of the noise is described.

The third logic circuit of the Schmitt circuit may have a different circuit configuration, as long as it executes the same operation.

Therefore, in a second embodiment, an example of the configuration of a Schmitt circuit including a third logic circuit C3′ that has a circuit configuration different from that of the first embodiment will be described.

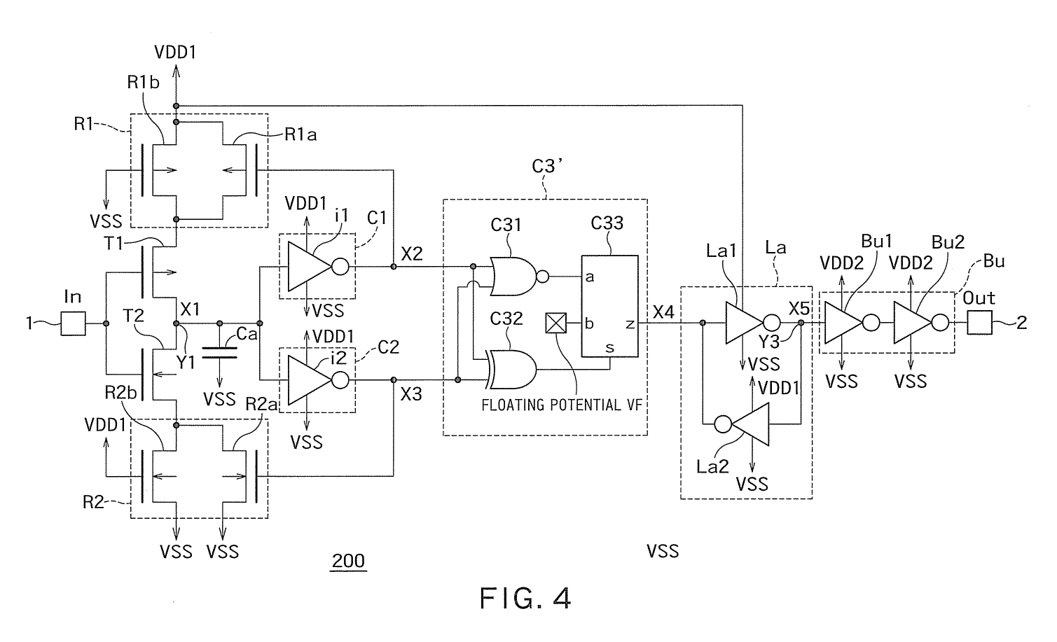

FIG. 4 is a circuit diagram showing an example of the configuration of a Schmitt circuit 200 according to the second embodiment. In FIG. 4, the same reference numerals as those of FIG. 1 denote the same components as those of FIG. 1.

As shown in FIG. 4, the Schmitt circuit 200 includes an input terminal 1, an output terminal 2, a first conductivity type first transistor (pMOS transistor) T1, a second conductivity type second transistor (nMOS transistor) T2, a first logic circuit C1, a second logic circuit C2, a third logic circuit C3′, a first variable resistance circuit R1, a second variable resistance circuit R2, a latch circuit La, an output buffer Bu, and a capacitor Ca, similar to the Schmitt circuit 100 according to the first embodiment.

In this case, similar to the first embodiment, the third logic circuit C3′ outputs any one of a third potential (in this case, a first potential VDD1 is selected), a fourth potential (in this case, a second potential VSS is selected) different from the third potential, and a floating potential VF that is floating from the third and fourth potentials (first and second potentials VDD1 and VSS) as a signal X4 output from an output unit z, according to the output signal X2 from the first logic circuit C1 and the output signal X3 from the second logic circuit C2.

The third logic circuit C3′ includes a NOR circuit C31, an XOR circuit C32, and a multiplexer C33.

The NOR circuit C31 receives an output of the first logic circuit C1 and an output of the second logic circuit C2.

The XOR circuit C32 receives the output of the first logic circuit C1 and the output of the second logic circuit C2.

The input terminal a of the multiplexer C33 receives the output signal of the NOR circuit C31 and the input terminal b thereof receives the floating potential. The multiplexer C33 outputs the potential of the input terminal a or the input terminal b as the output signal X4 from the output unit z, according to the output signal of the XOR circuit C32 input to a set terminal s thereof.

Next, the operation of the Schmitt circuit 200 that has the above configuration will be described.

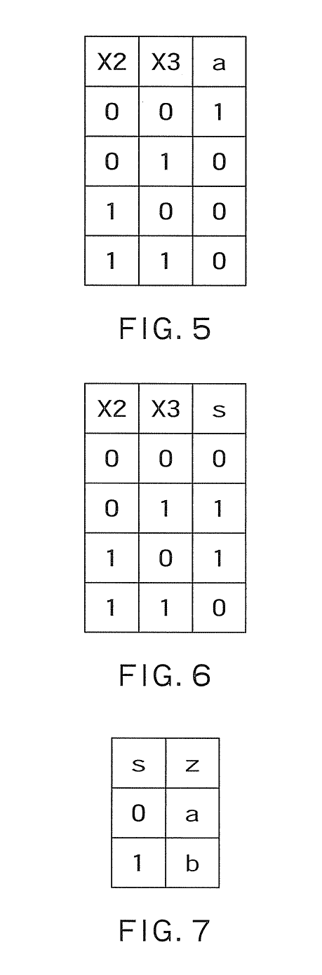

FIG. 5 shows an example of the logical level of the output of the NOR circuit C31 shown in FIG. 4. FIG. 6 shows an example of the logical level of the output of the XOR circuit C32 shown in FIG. 4. FIG. 7 shows an example of the logical level of the output of the multiplexer C33 shown in FIG. 4. In these drawings, the logical level “0” indicates a state where the logical level of a signal is a “Low” level and the logical level “1’ indicates a state where the logical level of the signal is a “High” level.

As shown in FIG. 5, the NOR circuit C31 outputs the logical level “1” when the output signals X2 and X3 have the logical levels “0” and “0,” respectively and outputs the logical level “0” when the output signals X2 and X3 have the logical levels “1” and “1,” respectively.

As shown in FIG. 6, the XOR circuit C32 outputs the logical level “0” when the output signals X2 and X3 have the logical levels “0” and “0,” respectively or “1” and “1,” respectively, and outputs the logical level “1” when the output signals X2 and X3 have the logical levels “0” and “1,” respectively or “1” and “0,” respectively.

As shown in FIG. 7, the multiplexer C33 selects and outputs the potential (that is, the output signal of the NOR circuit C31) of the input terminal a, when the logical level of the output signal of the XOR circuit C32 input to the set terminal s is “0”. Meanwhile, the multiplexer C33 selects and outputs the potential (that is, the floating potential VF) of the input terminal b, when the logical level of the output signal of the XOR circuit C32 input to the set terminal is “1.”

Thereby, similar to the first embodiment, when the logical levels of the output signals X2 and X3 are “0” and “0,” respectively, the third logic circuit C3′ outputs “1” (third potential (in this case, the first potential VDD1 is selected). Similar to the first embodiment, when the logical levels of the output signals X2 and X3 are “1” and “1,” respectively, the third logic circuit C3′ outputs “0” (fourth potential (in this case, the second potential VSS is selected). Similar to the first embodiment, when the logical levels of the output signals X2 and X3 are “1” and “0,” respectively or “0” and “1,” respectively, the third logic circuit C3′ outputs a signal where the logical level is indefinite.

That is, the relationship between the logic levels of the output signals X2 and X3 of the first and second logic circuits C1 and C2 and the logical level of the output signal X4 of the third logic circuit C3′ is the same as that of FIG. 2.

Therefore, the operation of the Schmitt circuit 200 is the same as that of the Schmitt circuit 100 according to the first embodiment.

That is, similar to the first embodiment, the Schmitt circuit 200 does not have a DC path where noise is output, and outputs the output signal Out where the logical level is definite, according to the input signal In.

As such, according to the Schmitt circuit according to the second embodiment, the transmission of the noise can be further suppressed, similar to the first embodiment.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A Schmitt circuit, comprising:
an input terminal into which an input signal is input;
an output terminal from which an output signal is output;
an input logic circuit that receives the input signal and has a threshold voltage that is variable;
a first logic circuit that receives an output signal of the input logic circuit and has a first threshold voltage;
a second logic circuit that receives the output signal of the input logic circuit and has a second threshold voltage lower than the first threshold voltage;
a variable resistance circuit that adjusts the threshold voltage of the input logic circuit in accordance with an output signal of the first logic circuit and an output signal of the second logic circuit;
a third logic circuit that receives the output signal of the first logic circuit and the output signal of the second logic circuit, outputs a floating potential in the case where a potential of an input signal of the third logic circuit is between the first threshold voltage and the second threshold voltage, and outputs a fixed potential in the case where the potential of the input signal of the third logic circuit is equal to or exceeds the first threshold voltage or is equal to or below the second threshold voltage; and
a signal holding circuit connected to the output terminal and holds an output of the third logic circuit.

2. The Schmitt circuit according to claim 1, further comprising an output buffer that includes an even number of output inverters connected in series between the signal holding circuit and the output terminal.

3. The Schmitt circuit according to claim 1, further comprising a capacitor that is connected between an output unit of the input logic circuit and a fixed potential.

4. The Schmitt circuit according to claim 2, further comprising a capacitor that is connected between an output unit of the input logic circuit and a fixed potential.

5. The Schmitt circuit according to claim 1, wherein
the first logic circuit is a first inverter that outputs a signal obtained by inverting a logical level of the output signal of the input logic circuit on the basis of the first threshold voltage, and
the second logic circuit is a second inverter that outputs a signal obtained by inverting a logical level of the output signal of the input logic circuit on the basis of the second threshold voltage.

6. The Schmitt circuit according to claim 2, wherein the first logic circuit is a first inverter that outputs a signal obtained by inverting a logical level of the output signal of the input logic circuit on the basis of the first threshold voltage, and
the second logic circuit is a second inverter that outputs a signal obtained by inverting the logical level of the output signal of the input logic circuit on the basis of the second threshold voltage.

7. The Schmitt circuit according to claim 3, wherein the first logic circuit is a first inverter that outputs a signal obtained by inverting a logical level of the output signal of the input logic circuit on the basis of the first threshold voltage, and
the second logic circuit is a second inverter that outputs a signal obtained by inverting the logical level of the output signal of the input logic circuit on the basis of the second threshold voltage.

8. The Schmitt circuit according to claim 1, wherein
the input logic circuit comprises:
a first transistor that includes one end connected to a first potential and a gate connected to the input terminal, the first transistor being a first conductivity type; and
a second transistor that includes one end connected to an other end of the first transistor, an other end connected to a second potential different from the first potential, and a gate connected to the input terminal, the second transistor being a second conductivity type.

9. The Schmitt circuit according to claim 1, wherein
the third logic circuit comprises:
a third transistor and a fourth transistor that are connected in series between a third potential and an output of the third logic circuit, wherein a gate of the third transistor connected to an output of the first logic circuit and a gate of the fourth transistor connected to an output of the second logic circuit, the third and fourth transistors being a first conductivity type;
a fifth transistor and a sixth transistor that are connected in series between a fourth potential different from the third potential and an output of the third logic circuit, wherein a gate of the fifth transistor connected to the output of the first logic circuit and a gate of the sixth transistor connected to the output of the second logic circuit, the fifth and sixth transistors being a second conductivity type.

10. The Schmitt circuit according to claim 2, wherein
the third logic circuit comprises:
a third transistor and a fourth transistor that are connected in series between a third potential and an output of the third logic circuit, wherein a gate of the third transistor connected to an output of the first logic circuit and a gate of the fourth transistor connected to an output of the second logic circuit, the third and fourth transistors being a first conductivity type;
a fifth transistor and a sixth transistor that are connected in series between a fourth potential different from the third potential and an output of the third logic circuit, wherein a gate of the fifth transistor connected to the output of the first logic circuit and a gate of the sixth transistor connected to the output of the second logic circuit, the fifth and sixth transistors being a second conductivity type.

11. The Schmitt circuit according to claim 3, wherein
the third logic circuit comprises:
a third transistor and a fourth transistor that are connected in series between a third potential and an output of the third logic circuit, wherein a gate of the third transistor connected to an output of the first logic circuit and a gate of the fourth transistor connected to an output of the second logic circuit, the third and fourth transistors being a first conductivity type;
a fifth transistor and a sixth transistor that are connected in series between a fourth potential different from the third potential and an output of the third logic circuit, wherein a gate of the fifth transistor connected to the output of the first logic circuit and a gate of the sixth transistor connected to the output of the second logic circuit, the fifth and sixth transistors being a second conductivity type.

12. The Schmitt circuit according to claim 1, wherein
the signal holding circuit comprises:
a first latching inverter having an input connected to the output of the third logic circuit; and
a second latching inverter having an input connected to an output of the first latching inverter, and having an output connected to the output of the third logic circuit.

13. The Schmitt circuit according to claim 2, wherein
the signal holding circuit comprises:
a first latching inverter having an input connected to the output of the third logic circuit; and
a second latching inverter having an input connected to an output of the first latching inverter, and having an output connected to the output of the third logic circuit.

14. The Schmitt circuit according to claim 3, wherein
the signal holding circuit comprises:
a first latching inverter having an input connected to the output of the third logic circuit; and
a second latching inverter having an input connected to an output of the first latching inverter, and having an output connected to the output of the third logic circuit.

15. The Schmitt circuit according to claim 8, wherein
the first potential is a power supply potential,
the second potential is a ground potential,
the first transistor is a pMOS transistor, and
the second transistor is a nMOS transistor.

16. A Schmitt circuit, comprising:
an input terminal into which an input signal is input;
an output terminal from which an output signal is output;
a first transistor that includes a gate connected to the input terminal, the first transistor being a first conductivity type;
a second transistor that includes one end connected to an other end of the first transistor and a gate connected to the input terminal, the second transistor being a second conductivity type;
a first logic circuit that compares a signal output from a terminal disposed between the other end of the first transistor and the one end of the second transistor with the first threshold voltage, and that inverts a logical level of an output signal on the basis of the comparison result;
a second logic circuit that compares the signal output from the terminal with the second threshold voltage, and that inverts a logical level of an output signal on the basis of the comparison result;
a first variable resistance circuit that is connected between a first potential and an one end of the first transistor, and has a resistance value controlled according to the output from the first logic circuit;
a second variable resistance circuit that is connected between a second potential different from the first potential and an other end of the second transistor, and has a resistance value controlled according to the output from the second logic circuit;
a third logic circuit that outputs any one of a third potential, a fourth potential different from the third potential, and the floating potential which is floating from the third and fourth potentials, according to the output signal from the first logic circuit and the output signal from the second logic circuit;
a latch circuit that latches a signal output from the third logic circuit and outputs a signal; and
an output buffer having an input connected to an output of the latch circuit, and having an output connected to the output terminal.

17. The Schmitt circuit according to claim 16, wherein
the first logic circuit is a first inverter that outputs a signal obtained by inverting a logical level of the signal output from the terminal on the basis of the first threshold voltage, and
the second logic circuit is a second inverter that outputs a signal obtained by inverting a logical level of the signal output from the terminal on the basis of the second threshold voltage.

18. The Schmitt circuit according to claim 16,
wherein the first variable resistance circuit comprises:
a first resistance transistor connected between the first potential and the one end of the first transistor, the first resistance transistor having a gate connected to the output of the first logic circuit, and the first resistance transistor being the first conductivity type; and
a second resistance transistor connected in parallel to the first resistance transistor between the first potential and the one end of the first transistor, a first fixed voltage being applied to a gate of the second resistance transistor to flow a current, and the second resistance transistor being the first conductivity type, and
wherein the second variable resistance circuit comprises:
a third resistance transistor connected between the second potential and the other end of the second transistor, the third resistance transistor having a gate connected to the output of the second logic circuit, and the third resistance transistor being the second conductivity type; and
a fourth resistance transistor connected in parallel to the third resistance transistor between the second potential and the other end of the second transistor, a second fixed voltage being applied to a gate of the fourth resistance transistor to flow a current, and the fourth resistance transistor being the second conductivity type.

19. The Schmitt circuit according to claim 17,
wherein the first variable resistance circuit comprises:
a first resistance transistor connected between the first potential and the one end of the first transistor, the first resistance transistor having a gate connected to the output of the first logic circuit, and the first resistance transistor being the first conductivity type; and
a second resistance transistor connected in parallel to the first resistance transistor between the first potential and the one end of the first transistor, a first fixed voltage being applied to a gate of the second resistance transistor to flow a current, and the second resistance transistor being the first conductivity type, and
wherein the second variable resistance circuit comprises:
a third resistance transistor connected between the second potential and the other end of the second transistor, the third resistance transistor having a gate connected to the output of the second logic circuit, and the third resistance transistor being the second conductivity type; and
a fourth resistance transistor connected in parallel to the third resistance transistor between the second potential and the other end of the second transistor, a second fixed voltage being applied to a gate of the fourth resistance transistor to flow a current, and the fourth resistance transistor being the second conductivity type.

20. The Schmitt circuit according to claim 16, wherein
the first potential is a power supply potential,
the second potential is a ground potential,
the first transistor is a pMOS transistor, and
the second transistor is a nMOS transistor.
